(19) United States
(12) Patent Application Publication
(10) Pub. No.: US 2025/0324698 A1
(43) Pub. Date: Oct. 16, 2025

(54) SILICON CARBIDE SEMICONDUCTOR WAFER, MANUFACTURING METHOD OF SILICON CARBIDE SEMICONDUCTOR WAFER, AND SILICON CARBIDE SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: HIROAKI FUJIBAYASHI, Nisshin-shi (JP); SHINICHI HOSHI, Nisshin-shi (JP); JUNICHI UEHARA, Kariya-city (JP); YUICHI TAKEUCHI, Kariya-city (JP); TAKUMI TSUNO, Kariya-city (JP)

(21) Appl. No.: 19/059,779

(22) Filed: Feb. 21, 2025

(30) Foreign Application Priority Data
Apr. 16, 2024 (JP) 2024-066406

(51) Int. Cl. H10D 62/832; H10D 62/60; H10D 62/834

(52) U.S. Cl. CPC H10D 62/8325; H10D 62/605; H10D 62/834

(57) ABSTRACT

An SiC semiconductor layer formed on an SiC semiconductor substrate includes a first layer and a second layer. The first layer is doped with an element controlling a conductivity type and an element not controlling the conductivity type. Within a plane of the first layer, a concentration of the element not controlling the conductivity type is uniform at a center portion and an outer edge portion. The second layer is doped with the element controlling the conductivity type, and is not doped with the element not controlling the conductivity type or is doped with the element not controlling the conductivity type at a lower concentration than the first layer. Within a plane of the second layer, a high and low concentration relationship of the element controlling the conductivity type at the center portion and the outer edge portion is reversed from that in the first layer.

### CROSS REFERENCE TO RELATED APPLICATION

The present application claims the benefit of priority from Japanese Patent Application No. 2024-066406 filed on Apr. 16, 2024. The entire disclosure of the above application is incorporated herein by reference.

### TECHNICAL FIELD

The present disclosure relates to a silicon carbide (hereinafter referred to as SiC) semiconductor wafer, a manufacturing method of an SiC semiconductor wafer, and an SiC semiconductor device.

### BACKGROUND

Conventionally, various methods of epitaxially growing an SiC semiconductor layer on an SiC semiconductor substrate to form an SiC semiconductor wafer have been proposed.

### SUMMARY

The present disclosure provides an SiC semiconductor wafer including an SiC semiconductor substrate, and an SiC semiconductor layer formed of an epitaxially grown layer on the SiC semiconductor substrate. The SiC semiconductor layer includes a first layer and a second layer. The first layer is doped with an element that controls a conductivity type of the SiC semiconductor layer and an element that does not control the conductivity type of the SiC semiconductor layer. One of the elements substitutes for Si sites and another of the elements substitutes for C sites. Within a plane of the first layer, a concentration of the element that controls the conductivity type is different at a center portion and an outer edge portion, and a concentration of the element that does not control the conductivity type is uniform at the center portion and the outer edge portion. The second layer is doped with the element that controls the conductivity type, and is not doped with the element that does not control the conductivity type or is doped with the element that does not control the conductivity type at a lower concentration than the first layer. Within a plane of the second layer, a high and low concentration relationship of the element that controls the conductivity type at the center portion and the outer edge portion is reversed from that in the first layer.

The present disclosure also provides a manufacturing method of an SiC semiconductor wafer that includes preparing an SiC semiconductor substrate, and epitaxially growing an SiC semiconductor layer on the SiC semiconductor substrate. The epitaxially growing of the SiC semiconductor layer includes forming a first layer and forming a second layer. The forming of the first layer includes doping with an element that controls a conductivity type of the SiC semiconductor layer and an element that does not control the conductivity type of the SiC semiconductor layer such that, within a plane of the first layer, a concentration of the element that controls the conductivity type is different at a center portion and an outer edge portion, and a concentration of the element that does not control the conductivity type is uniform at the center portion and the outer edge portion. The forming of the second layer includes doping with the element that controls the conductivity type, and not doping with the element that does not control the conductivity type or doping with the element that does not control the conductivity type at a lower concentration than the first layer such that, within a plane of the second layer, a high and low concentration relationship of the element that controls the conductivity type at the center portion and the outer edge portion is reversed from that in the first layer.

The present disclosure also provides an SiC semiconductor device including an SiC semiconductor substrate, and an SiC semiconductor layer formed of an epitaxially grown layer on the SiC semiconductor substrate, and forming a buffer layer. The SiC semiconductor layer includes a first layer and a second layer. The first layer is doped with an element that controls a conductivity type of the SiC semiconductor layer and an element that does not control the conductivity type of the SiC semiconductor layer. One of the elements substitutes for Si sites and another of the elements substitutes for C sites. The second layer is doped with the element that controls the conductivity type, and is not doped with the element that does not control the conductivity type or is doped with the element that does not control the conductivity type at a lower concentration than the first layer.

### BRIEF DESCRIPTION OF DRAWINGS

Objects, features and advantages of the present disclosure will become apparent from the following detailed description made with reference to the accompanying drawings. In the drawings:

FIG. 1 is a cross-sectional view of an SiC semiconductor wafer according to a first embodiment of the present disclosure;

FIG. 2A is a diagram showing V concentration profiles in a depth direction of an SiC semiconductor layer at a center portion and an outer edge portion of the SiC semiconductor layer;

FIG. 2B is a diagram showing N concentration profiles in the depth direction of the SiC semiconductor layer at the center portion and the outer edge portion of the SiC semiconductor layer;

FIG. 3 is a schematic diagram of an epitaxial growth apparatus;

FIG. 4A is a graph showing a relationship between a distance from a wafer center and an N concentration in a first layer;

FIG. 4B is a graph showing a relationship between the distance from the wafer center and a V concentration in the first layer;

FIG. 5A is a diagram showing results of measuring the N concentration at the wafer center and at a position 65 mm away from the wafer center in the first layer;

FIG. 5B is a diagram showing results of measuring the V concentration at the wafer center and at the position 65 mm away from the wafer center in the first layer;

FIG. 6A is a graph showing a relationship between a distance from the wafer center and an N concentration in a second layer;

FIG. 6B is a graph showing a relationship between the distance from the wafer center and a V concentration in the second layer;

FIG. 7A is a diagram showing results of measuring the N concentration at the wafer center and at a position 65 mm away from the wafer center in the second layer; and

FIG. 7B is a diagram showing results of measuring the V concentration at the wafer center and at the position 65 mm away from the wafer center in the second layer.

### DETAILED DESCRIPTION

When epitaxially growing an SiC semiconductor layer on an SiC semiconductor substrate to form an SiC semiconductor wafer, for example, a reaction gas containing a mixture of silicon (Si) source gas, carbon (C) source gas, dopant gas, and carrier gas is introduced into a center portion of the SiC semiconductor substrate placed on a rotating support table, and a similar reaction gas is also introduced into an outer edge portion of the SiC semiconductor substrate. When a C/Si ratio of the reaction gas introduced into the center portion is set to be different from that of the reaction gas introduced into the outer edge portion, it is possible to restrict in-plane variations in the doping concentration and the film thickness of the SiC semiconductor layer and make the SiC semiconductor layer uniform.

When epitaxially growing the SiC semiconductor layer, elements with different substitution sites, for example, aluminum (Al), phosphorus (P), or vanadium (V) which substitutes for Si sites and nitrogen (N) or boron (B) which substitutes for C sites, may be simultaneously doped. In this case, simply changing C/Si ratios at the center portion and the outer edge portion makes it difficult to achieve epitaxial growth while making the concentrations of the two types of dopants uniform and restricting in-plane variations in a film thickness.

An SiC semiconductor wafer according to a first aspect of the present disclosure has a disk shape and has a center portion and an outer edge portion, and includes an SiC semiconductor substrate, and an SiC semiconductor layer formed of an epitaxially grown layer on the SiC semiconductor substrate. The SiC semiconductor layer includes a first layer and a second layer. The first layer is doped with an element that controls a conductivity type of the SiC semiconductor layer and an element that does not control the conductivity type of the SiC semiconductor layer. One of the elements substitutes for Si sites and another of the elements substitutes for C sites. Within a plane of the first layer, a concentration of the element that controls the conductivity type is different at the center portion and the outer edge portion, and a concentration of the element that does not control the conductivity type is uniform at the center portion and the outer edge portion. The second layer is doped with the element that controls the conductivity type, and is not doped with the element that does not control the conductivity type or is doped with the element that does not control the conductivity type at a lower concentration than the first layer. Within a plane of the second layer, a high and low concentration relationship of the element that controls the conductivity type at the center portion and the outer edge portion is reversed from that in the first layer.

With this configuration, even if there are variations in the concentrations of the element that controls the conductivity type and the element that does not control the conductivity type in individual layers of the first layer and second layer, the SiC semiconductor layer can have uniform concentration averaged over the total thickness of the SiC semiconductor layer at the center portion and the outer edge portion. Therefore, when doping elements with different substitution sites, it is possible to provide a SiC semiconductor wafer that can restrict in-plane variations in the concentrations of two types of dopants and in the film thickness.

A manufacturing method according to a second aspect of the present disclosure is a manufacturing method of an SiC semiconductor wafer having a disk shape and having a center portion and an outer edge portion, and includes preparing an SiC semiconductor substrate, and epitaxially growing an SiC semiconductor layer on the SiC semiconductor substrate. The epitaxially growing of the SiC semiconductor layer includes forming a first layer and forming a second layer. The forming of the first layer includes doping with an element that controls a conductivity type of the SiC semiconductor layer and an element that does not control the conductivity type of the SiC semiconductor layer such that, within a plane of the first layer, a concentration of the element that controls the conductivity type is different at the center portion and the outer edge portion, and a concentration of the element that does not control the conductivity type is uniform at the center portion and the outer edge portion. One of the elements substitutes for Si sites and another of the elements substitutes for C sites. The forming of the second layer includes doping with the element that controls the conductivity type, and not doping with the element that does not control the conductivity type or doping with the element that does not control the conductivity type at a lower concentration than the first layer such that, within a plane of the second layer, a high and low concentration relationship of the element that controls the conductivity type at the center portion and the outer edge portion is reversed from that in the first layer.

According to this manufacturing method, even if there are variations in the concentrations of the element that controls the conductivity type and the element that does not control the conductivity type in individual layers of the first layer and second layer, the SiC semiconductor layer can have uniform concentration averaged over the total thickness of the SiC semiconductor layer at the center portion and the outer edge portion. Therefore, when doping elements with different substitution sites, it is possible to manufacture a SiC semiconductor wafer that can restrict in-plane variations in the concentrations of two types of dopants and in the film thickness.

An SiC semiconductor device according to a third aspect of the present disclosure includes an SiC semiconductor substrate, and an SiC semiconductor layer formed of an epitaxially grown layer on the SiC semiconductor substrate, and forming a buffer layer. The SiC semiconductor layer includes a first layer and a second layer. The first layer is doped with an element that controls a conductivity type of the SiC semiconductor layer and an element that does not control the conductivity type of the SiC semiconductor layer. One of the elements substitutes for Si sites and another of the elements substitutes for C sites. The second layer is doped with the element that controls the conductivity type, and is not doped with the element that does not control the conductivity type or is doped with the element that does not control the conductivity type at a lower concentration than the first layer.

With this configuration, even if there are variations in the concentrations of the element that controls the conductivity type and the element that does not control the conductivity type in individual layers of the first layer and second layer, the SiC semiconductor layer can have uniform concentration averaged over the total thickness of the SiC semiconductor layer at the center portion and the outer edge portion. Thus, in the SiC semiconductor device including the first layer and the second layer, whether it is manufactured using the center portion or the outer edge portion of the SiC semiconductor wafer, similar functionality is obtained and the electrical characteristics are uniform. It is therefore possible to provide the SiC semiconductor layer in which variations in the concentrations of the two types of dopants and in the film thickness are restricted.

Embodiments of the present disclosure will be described below with reference to the drawings. In the following embodiments including other embodiments to be described below, the same or equivalent components will be described with the same reference numerals.

### First Embodiment

First, an SiC semiconductor wafer according to a first embodiment of the present disclosure will be described. The SiC semiconductor wafer is used for manufacturing SiC semiconductor devices such as metal oxide semiconductor field effects (MOSFETs).

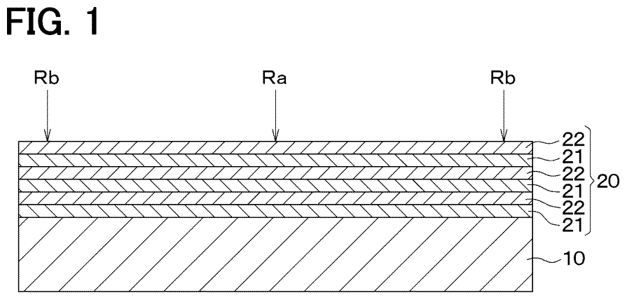

As shown in FIG. 1, the SiC semiconductor wafer of the present embodiment is configured by epitaxially growing an SiC semiconductor layer 20 on an SiC semiconductor substrate 10.

The SiC semiconductor substrate 10 is, for example, composed of n-type 4H-SiC having a silicon (Si) face on one side and a carbon (C) face on the other side, more specifically, having an off-direction in a <11-20> direction and an off-angle of 0 to 8 degrees with respect to a (0001) Si face. The SiC semiconductor substrate 10 is used to form a drain region in a MOSFET However, the SiC semiconductor substrate 10 shown here is just an example, and a semiconductor substrate in the present disclosure is not limited to this example. The off-direction means “a direction parallel to a vector obtained by projecting a normal vector of a growth surface, in the present embodiment, a vector in a <0001> direction that is a normal vector with respect to the (0001) Si face, onto a main surface of the SiC semiconductor substrate 10”.

The SiC semiconductor layer 20 is epitaxially grown on the SiC semiconductor substrate 10. For example, the SiC semiconductor layer 20 is used as a buffer layer in the MOSFET, that is, a layer located between the SiC semiconductor substrate 10 constituting a drain region and a drift layer formed above the drain region. The buffer layer plays a role of buffering mismatch caused by differences in concentration of impurities that act as carriers when the drift layer is formed above the SiC semiconductor substrate 10. An n-type impurity concentration of the SiC semiconductor substrate 10 is set to, for example, 5.0×10¹⁸ cm⁻³ or more, and an n-type impurity concentration of the drift layer is set to, for example, 5.0×10¹⁶ cm⁻³ or less. In this case, the n-type impurity concentration of the buffer layer is set to a concentration between the n-type impurity concentration of the SiC semiconductor substrate 10 and the n-type impurity concentration of the SiC semiconductor layer 20, and is set to, for example, 1.0×10¹⁷ cm⁻³ or more and 5.0×10¹⁸ cm⁻³ or less.

The SiC semiconductor layer 20 is configured by laminating a first layer 21 and a second layer 22. The first layer 21 and the second layer 22 are each formed with at least one layer, but it is preferable that a plurality of sets of the first layer 21 and the second layer 22 are repeatedly formed. The number of layers of the first layer 21 and the second layer 22 is the same, and FIG. 1 shows a case where the SiC semiconductor layer 20 is formed by three sets of alternating layers, each consisting of one first layer 21 and one second layer 22, laminated together.

The first layer 21 is formed by doping N and V as elements into SiC. N is an n-type impurity, and is used as a dopant for controlling the conductivity type to make the first layer 21 n-type. V is doped to obtain an effect of restricting current-induced degradation of a diode included in a SiC semiconductor device manufactured using the SiC semiconductor wafer.

For example, when a SiC semiconductor device including a switching element such as a MOSFET is manufactured using the SiC semiconductor wafer in which the SiC semiconductor layer 20 is formed on the SiC semiconductor substrate 10, a built-in diode is formed. When this SiC semiconductor device is applied to an inverter circuit or the like, and the built-in diode operates in bipolar mode due to the freewheeling operation during switching, there is a possibility that basal plane dislocations (hereinafter referred to as BPDs) will expand into Shockley stacking faults (hereinafter referred to as SSFs). That is, holes passing near BPDs recombine with electrons in an n-type layer, generating large recombination energy, which causes BPDs to expand into SSFs. Since SSFs occupy a larger area than BPDs and are defects that are likely to cause degradation of the electrical characteristics of SiC semiconductor devices, that is, current-introduced degradation of diodes, it is desirable to restrict the expansion of BPDs into SSFs. V has the effect of restricting the expansion of BPDs into SSFs.

In this manner, the first layer 21 is doped with N to be n-type, and is also doped with V to restrict degradation of the diode during conduction. The substitution sites of N and V are different, V substitutes for Si sites, and N substitutes for C sites. The first layer 21 contains both of these elements with different substitution sites.

The second layer 22 is formed by doping N as an element into SiC. Alternatively, the second layer 22 is doped with N and V as elements, with the V doping amount being sufficiently smaller than that of the first layer 21, for example, 1/10 or less. Similarly to the first layer 21, the second layer 22 is doped with N to be n-type.

In this manner, the SiC semiconductor layer 20 is formed by alternately laminating the first layer 21 doped with N and V and the second layer 22 doped with only N or N and a small amount of V. The thicknesses of the first layers 21 and the second layers 22 may be determined according to an intended use, and may be any thickness that provides a function corresponding to the intended use. For example, when the SiC semiconductor layer 20 is used as a buffer layer, the first layers 21 and the second layers 22 each have a thickness of about 0.1 to 0.5 μm, and the total thickness of the SiC semiconductor layer 20 is defined by the number of layers of the first layers 21 and the second layers 22 that are laminated. The SiC semiconductor wafer has a disk shape, and each of the first layers 21 has the same thickness at a center portion Ra and an outer edge portion Rb of the SiC semiconductor wafer within the same layer. Similarly, each of the second layers 22 has the same thickness at the center portion Ra and the outer edge portion Rb of the SiC semiconductor wafer within the same layer.

It is preferable that the thicknesses of the first layers 21 and the second layers 22 are the same for all pairs of the first layer 21 and the second layer 22, each of which is made up of one first layer 21 and one second layer 22 formed successively. However, it is sufficient that the thicknesses of the first layers 21 and the second layers 22 match at least in each pair.

Even when concentration profiles at the center portion Ra and the outer edge portion Rb are different in each layer of the first layers 21 and the second layers 22, each of the N concentration and the V concentration is almost equal at the center portion Ra and at the outer edge portion Rb when considering the first layer 21 and the second layer 22 for each pair as a whole. Here, regarding positions of the center portion Ra and the outer edge portion Rb in the SiC semiconductor wafer, for example, the center portion Ra is a position 0 mm from the center of the SiC semiconductor wafer, and the outer edge portion Rb is a position approximately 10 mm from an outer edge of the SiC semiconductor wafer. If a diameter of the SiC semiconductor wafer is 6 inches, the center portion Ra is a position 0 mm from the center of the SiC semiconductor wafer, and the outer edge portion Rb is a position 65 mm away from the center of the SiC semiconductor wafer, since the outer edge of a 6-inch wafer is approximately 75 mm away from the center of the SiC semiconductor wafer. If the SiC semiconductor wafer is 8 inches, the center portion Ra is a position 0 mm from the center of the SiC semiconductor wafer, and the outer edge portion Rb is a position 90 mm away from the center of the SiC semiconductor wafer, since the outer edge of an 8-inch wafer is approximately 100 mm from the center of the SiC semiconductor wafer.

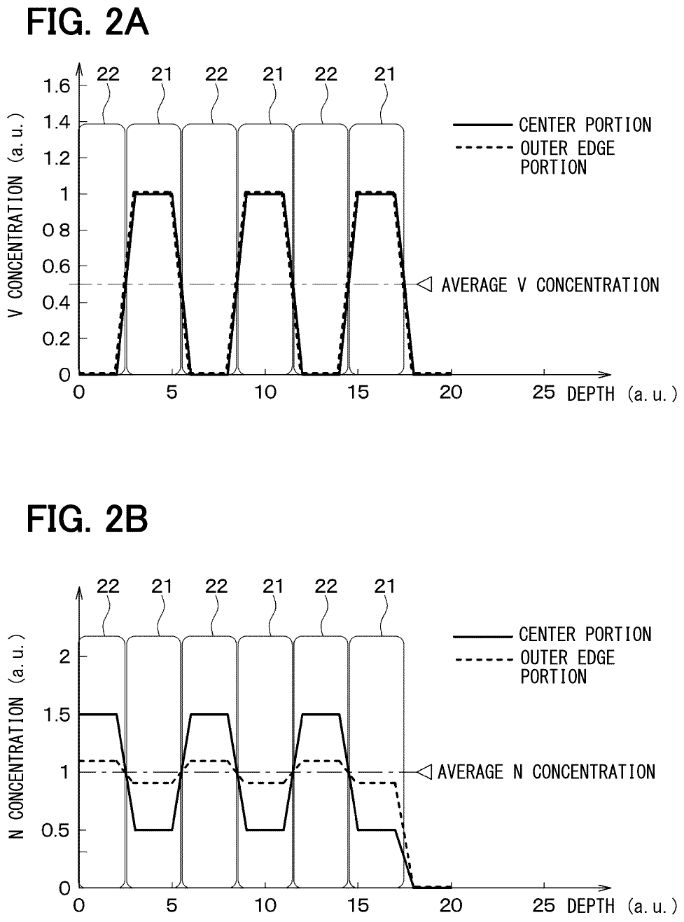

As shown in FIG. 2A, the V concentration has a similar profile in the depth direction, that is, with respect to the depth from the surface of the SiC semiconductor layer 20 opposite to the SiC semiconductor substrate 10, at the center portion Ra and the outer edge portion Rb. Specifically, in the first layers 21, the V concentration matches at a predetermined value at the center portion Ra and the outer edge portion Rb. In the second layers 22, the V concentration is approximately zero at both the center portion Ra and the outer edge portion Rb. The average value obtained by dividing the V concentration of the entire SiC semiconductor layer 20, including the first layers 21 and the second layers 22, by the entire thickness of the SiC semiconductor layer 20 (hereinafter referred to as the average V concentration) is the median value of the V concentration in the first layers 21 and the V concentration in the second layers 22. This value is within the range of the V concentration required for the SiC semiconductor layer 20.

On the other hand, as shown in FIG. 2B, the N concentration has different profiles in the depth direction at the center portion Ra and the outer edge portion Rb. Specifically, in the first layers 21, the center portion Ra has a lower N concentration than the outer edge portion Rb, and in the second layers 22, the center portion Ra has a higher N concentration than the outer edge portion Rb. At the outer edge portion Rb, the N concentration is lower in the first layers 21 than in the second layers 22, but the difference is small, and the N concentration is approximately the same in the first layers 21 and the second layers 22. On the other hand, at the center portion Ra, the N concentration is lower in the first layers 21 than in the second layers 22, and the difference is larger compared to the outer edge portion Rb. However, the average value obtained by dividing the V concentration of the entire SiC semiconductor layer 20, including the first layers 21 and the second layers 22, by the entire thickness of the SiC semiconductor layer 20 (hereinafter referred to as the average N concentration) matches at the center portion Ra and the outer edge portion Rb. In other words, the median value of the N concentration in the first layers 21 and the N concentration in the second layers 22 is approximately the same at the center portion Ra and the outer edge portion Rb. This value is within the range of the N concentration required for the SiC semiconductor layer 20.

In this manner, the V concentration is high in the first layers 21 and low in the second layers 22, but the average V concentration is set within a predetermined range. That is, when the SiC semiconductor layer 20 is used as a buffer layer, the average V concentration is set to a concentration that satisfies the current degradation of the diode. Furthermore, although the profiles of the N concentration are different at the center portion Ra and the outer edge portion Rb, the average N concentration matches within the predetermined range at the center portion Ra and the outer edge portion Rb. That is, when the SiC semiconductor layer 20 is used as a buffer layer, the concentration is set to be capable of buffering mismatch due to the difference in concentration of impurities that serve as carriers between the SiC semiconductor substrate 10 and the drift layer.

Accordingly, even if each of the V concentration and the N concentration vary among the individual layers of the first layers 21 and the second layers 22, each of the average V concentration and the average N concentration can be the same at the center portion Ra and the outer edge portion Rb in the SiC semiconductor layer 20. Therefore, when doping elements with different substitution sites, it is possible to manufacture a SiC semiconductor wafer that can restrict in-plane variations in the concentrations of two types of dopants and in the film thickness.

Furthermore, when manufacturing an SiC semiconductor device using the above-described SiC semiconductor wafer, the semiconductor device is manufactured by fabricating semiconductor elements such as MOSFETs incorporating diodes in the same layout at both the center portion Ra and the outer edge portion Rb and then dicing the semiconductor wafer. In this case, although the profiles of the first layers 21 and the second layers 22 constituting the SiC semiconductor layer 20 are different between the MOSFET formed at the center portion Ra and the MOSFET formed at the outer edge portion Rb, each of the average V concentration and the average N concentration is the same between the MOSFET formed at the center portion Ra and the MOSFET formed at the outer edge portion Rb. Therefore, when the SiC semiconductor layer 20 is used as a buffer layer, the center portion Ra and the outer edge portion Rb can have the same function as the buffer layer, and the electrical characteristics can also be made uniform. It is therefore possible to provide a SiC semiconductor device with little variation in the concentrations of the two types of dopants and in the film thickness.

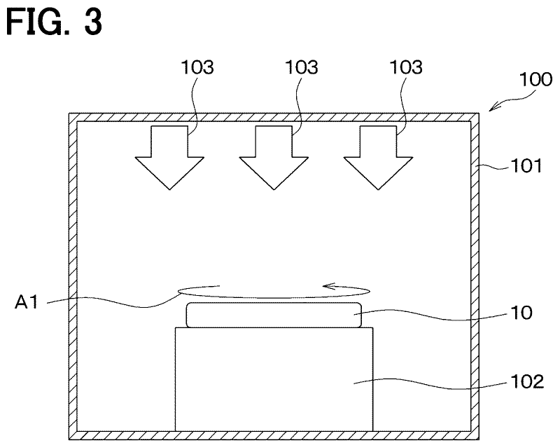

Next, a manufacturing method of the SiC semiconductor wafer according to the present embodiment will be described. The SiC semiconductor wafer is manufactured by growing the SiC semiconductor layer 20 on the SiC semiconductor substrate 10. In manufacturing the SiC semiconductor wafers, a gas supply system capable of introducing a silane-based gas serving as a Si source gas and a hydrocarbon-based gas serving as a C source gas and capable of adjusting the gas flow rate to make the C/Si ratio different between the center portion Ra and the outer edge portion Rb is used. For example, a chemical vapor deposition (CVD) apparatus for epitaxial growth shown in FIG. 3 is used. As the Si source gas, for example, silane (SiH₄) can be used, and as the C source gas, for example, propane (C₃H₈) can be used.

First, as the SiC semiconductor substrate 10, a substrate made of SiC single crystal having an off-axis direction of 0 to 8 degrees with respect to a (0001) Si face is prepared. Subsequently, as shown in FIG. 3, the SiC semiconductor substrate 10 is placed on a susceptor 102 in a chamber 101 of a CVD apparatus 100, and the SiC semiconductor substrate 10 is rotated as indicated by an arrow A1. In addition to the Si source gas and the C source gas, a process gas includes, for example, hydrogen (H₂) as a carrier gas, ammonia (NH₃) as a N dopant gas, and vanadium chloride (VCl₄) as a V dopant gas. Furthermore, the susceptor 102 is heated to heat the SiC semiconductor substrate 10 to 1600 to 1750° C. Then, a first layer growth process and a second layer growth process are repeatedly performed in the CVD apparatus 100 to epitaxially grow the SiC semiconductor layer 20.

### (i) First Layer Growth Process

The first layer growth process is a process of epitaxially growing the first layer 21. Specifically, the C/Si ratio is made different between the center portion Ra and the outer edge portion Rb, and the first layer 21 is grown with a profile that prioritizes making the in-plane distribution of the V concentration uniform, even if in-plane variations in the N concentration occur between the center portion Ra and the outer edge portion Rb. The term “making the in-plane distribution of the V concentration uniform” used herein means that the V concentration in the first layer 21 is uniform within a predetermined range within the plane of the SiC semiconductor wafer, and does not have to be completely uniform. That is, it is sufficient that the in-plane distribution of the V concentration is smaller than the in-plane distribution of the N concentration in the first layer 21 and that the V concentration is uniform within the plane. For example, it is sufficient that the variation in the V concentration between the center portion Ra and the outer edge portion Rb is within ±30% of the average value of the V concentration in the first layer 21.

For example, for C₃H₈ serving as the C source gas in the SiC source gas 103, the gas supply ratio at the center portion Ra is set to X, and the gas supply ratio at the outer edge portion Rb is set to 1-X. In addition, for SiH₄ serving as the Si source gas in the SiC source gas 103, the gas supply ratio at the center portion Ra is set to Y, and the gas supply ratio at the outer edge portion Rb is set to 1-Y The total supply amount of the SiC source gas 103 to the center portion Ra and the outer edge portion Rb is set to 1, and the supply amount is adjusted to correspond to the C/Si ratio in the chamber 101. Specifically, as shown in FIG. 3, in the CVD apparatus 100, there is a portion within chamber 101 where the SiC source gas 103 is supplied from a position corresponding to the center portion Ra of the SiC semiconductor substrate 10, and a portion where the SiC source gas 103 is supplied from a position corresponding to the outer edge portion Rb. The supply ratios of the C source gas and the Si source gas in the SiC source gas 103 corresponding to the center portion Ra and the SiC source gas 103 corresponding to the outer edge portion Rb are made different, so that the total supply amount of the SiC source gas 103 corresponds to the C/Si ratio in SiC growth.

When growing the first layer 21, the C source material gas and the Si source gas are set to a first distribution ratio (X1, Y1), that is, the gas supply ratio at the center portion Ra is set to X1 for the C source gas and to Y1 for the Si source gas. The first distribution ratio (X1, Y1) is the distribution ratio when the V concentration at the center portion Ra and the outer edge portion Rb becomes uniform when the SiC semiconductor layer 20 is formed in advance by an experiment. When the diameter of the SiC semiconductor substrate 10 is 6 inches, for example, a position 0 mm from the center of the SiC semiconductor wafer is defined as the center portion Ra, and a position 65 mm away from the center of the SiC semiconductor wafer is defined as the outer edge portion Rb, and the N concentration and V concentration are measured at each of these portions. The N concentration and V concentration can be determined by secondary ion mass spectrometry (SIMS), CV measurement, or the like.

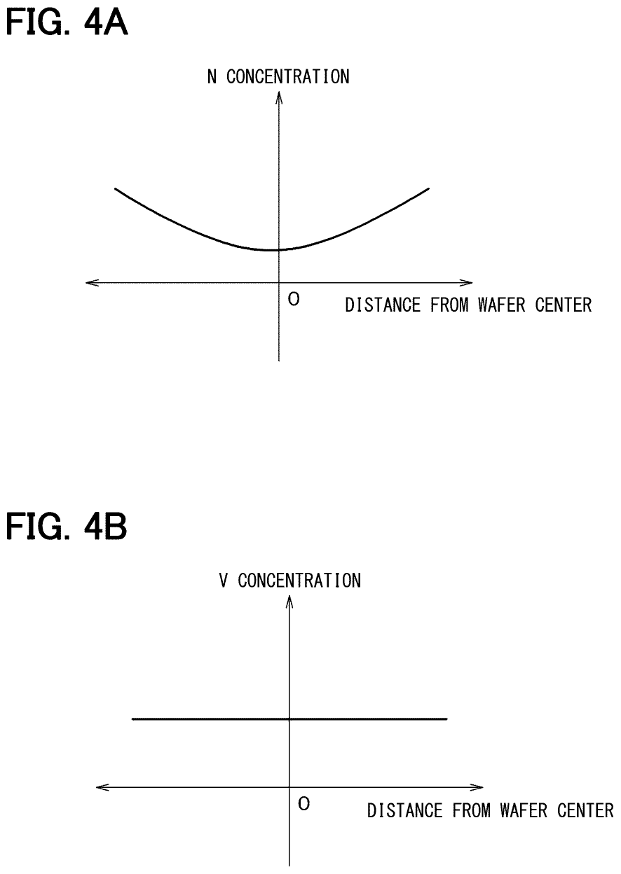

In this manner, when the first layer 21 is grown with the first distribution ratio (X1, Y1), as shown in FIG. 4A and FIG. 4B, the N concentration is lower at the center portion Ra than at the outer edge portion Rb, resulting in a concave relationship. In contrast, the V concentration can be adjusted within a predetermined range at the center portion Ra and the outer edge portion Rb.

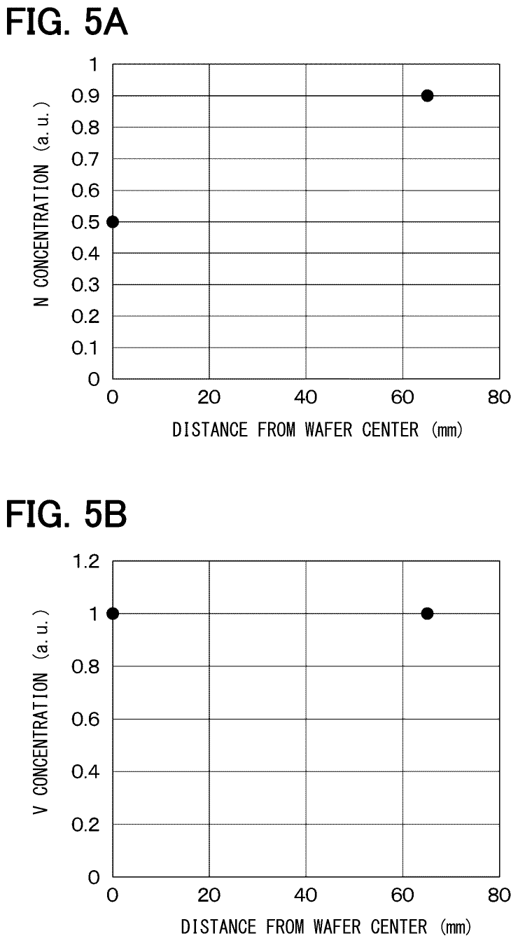

In an experiment, a first layer 21 was grown on a 6-inch SiC semiconductor substrate 10 with a first distribution ratio (X1, Y1), and the N concentration and V concentration were measured at the center portion Ra, which was a position 0 mm from the center of the SiC semiconductor wafer, and at the outer edge portion Rb, which was a position 65 mm away from the center of the SiC semiconductor wafer. As a result, the results shown in FIG. 5A and FIG. 5B were obtained, where the V concentration shown in FIG. 5B was approximately the same at the center portion Ra and the outer edge portion Rb, and the N concentration at the outer edge portion Rb shown in FIG. 5A was 1.8 to 1.9 times that at the center portion Ra.

### (ii) Second Layer Growth Process

The second layer growth process is a process of epitaxially growing the second layer 22. Specifically, the C/Si ratio is made different between the center portion Ra and the outer edge portion Rb, such that a high and low N concentration relationship at the center portion Ra and the outer edge portion Rb is reversed from that in the first layer 21. The V concentration is set to zero or sufficiently smaller than that of the first layer 21, for example, 1/10 or less of that of the first layer 21.

During the growth of the second layer 22, the distribution ratios of the C source gas and the Si source gas at the center portion Ra and the outer edge portion Rb are also set to be different from those during the growth of the first layer 21. Specifically, the C source gas and the Si source gas are set to a second distribution ratio (X2, Y2), that is, the gas supply ratio at the center portion Ra is set to X2 for the C source gas and to Y2 for the Si source gas. For example, when the N concentration of the first layer 21 grown with the first distribution ratio (X1, Y1) is lower at the center portion Ra than at the outer edge portion Rb, the second distribution ratio (X2, Y2) is set so that the C/Si ratio at the center portion Ra is lower than the first distribution ratio (X1, Y1). In other words, at least one of X1>X2 and Y1<Y2 should be satisfied. In addition, the second distribution ratio (X2, Y2) may be set as a distribution ratio when the relationship between the N concentrations at the center portion Ra and the outer edge portion Rb is reversed from that in the first layer 21 when the SiC semiconductor layer 20 is formed in advance by an experiment. In this case, the N concentration can be measured at the same position as when the first layer 21 was formed in the experiment. For example, if the diameter of the SiC semiconductor substrate 10 is 6 inches, the N concentration can be measured at positions 0 mm and 65 mm away from the center of the SiC semiconductor wafer as the center portion Ra and the outer edge portion Rb, respectively.

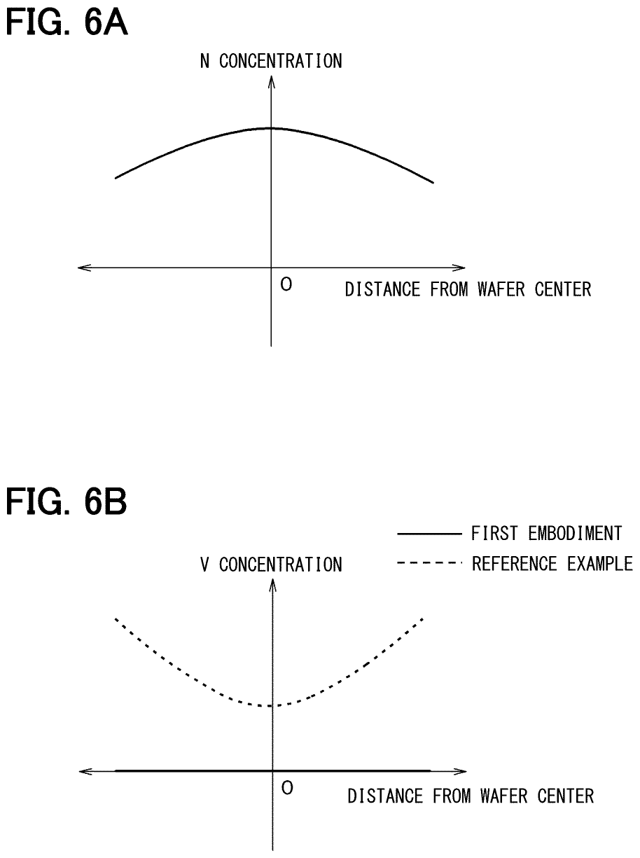

In this way, when the second layer 22 is grown with the second distribution ratio (X2, Y2), as shown in FIG. 6A, the N concentration is higher at the center portion Ra than at the outer edge portion Rb, resulting in a convex relationship. Therefore, the average N concentration can be adjusted within the predetermined range at both the center portion Ra and the outer edge portion Rb. Moreover, as shown by a solid line in FIG. 6B, the V concentration can be made almost zero at both the center portion Ra and the outer edge portion Rb. Therefore, the average V concentration calculated over the total thickness of the SiC semiconductor layer 20 is determined by the V concentration of the first layer 21, and the average V concentration can be uniform within predetermined range at both the center portion Ra and the outer edge portion Rb.

It is sufficient that the average N concentration is uniform within the predetermined range, and the average N concentration does not need to be exactly the same at the center portion Ra and the outer edge portion Rb. That is, it is sufficient that the variation is smaller than the in-plane distribution within the first layer 21 and the average N concentration is uniform within the plane. For example, it is sufficient that the variation in the average N concentration between the center portion Ra and the outer edge portion Rb is within ±30% of the average N concentration in the SiC semiconductor layer 20.

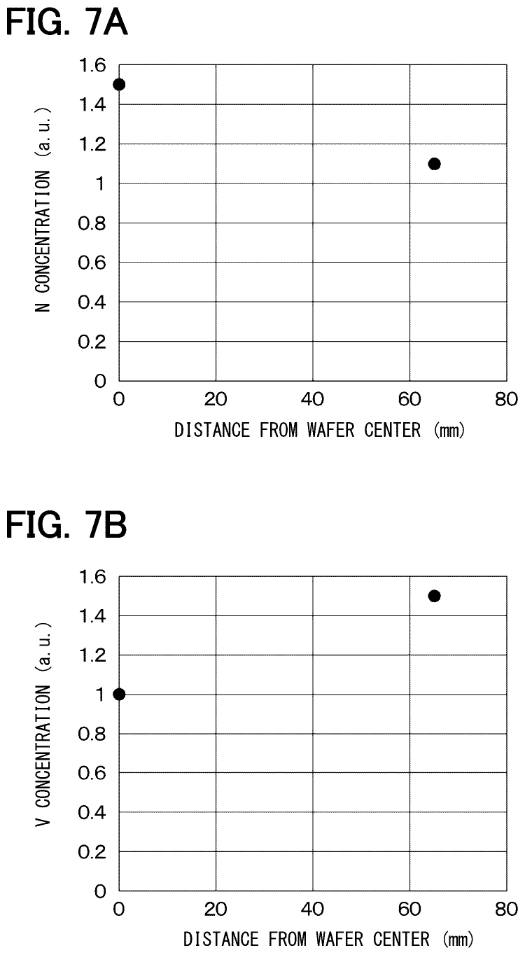

In an experiment, the second layer 22 was grown on a 6-inch SiC semiconductor substrate 10 with the second distribution ratio (X2, Y2), and the N concentration and V concentration were measured at the center portion Ra, which was a position 0 mm from the center of the SiC semiconductor wafer, and the outer edge portion Rb, which was a position 65 mm away from the center of the SiC semiconductor wafer. As a result, the results shown in FIG. 7A were obtained, and the N concentration at the outer edge portion Rb was about ⅔ times that at the center portion Ra.

As a reference example, the V concentration in the second layer 22 was investigated when the second layer 22 was grown with the second distribution ratio (X2, Y2) and a gas containing V was introduced in the same manner as in the growth of the first layer 21. As a result, the results shown in FIG. 7B were obtained, and the V concentration at the center portion Ra was lower than that at the outer edge portion Rb. This relationship is s concave relationship in which the V concentration is lower at the center portion Ra than at the outer edge portion Rb, as shown by a dashed line in FIG. 6B. Therefore, if the second layer 22 is doped with the same amount of V as the first layer 21, when the first layer 21 and the second layer 22 are considered as a whole, an in-plane variation in V concentration occurs. However, as in the present embodiment, if the V concentration in the second layer 22 is nearly zero or the V concentration in the second layer 22 is sufficiently lower than that in the first layer 21, it is possible to eliminate in-plane variation in the V concentration when considering the first layer 21 and the second layer 22 as a whole.

According to the manufacturing method of the SiC semiconductor wafer described above, even if there are variations in the V concentration and the N concentration in the individual layers of the first layers 21 and the second layers 22, each of the average V concentration and the average N concentration can be made uniform at the center portion Ra and the outer edge portion Rb. Therefore, when doping elements with different substitution sites, it is possible to manufacture a SiC semiconductor wafer that can restrict in-plane variations in the concentrations of two types of dopants and in the film thickness.

### Other Embodiments

While the present disclosure has been described in accordance with the embodiment described above, the present disclosure is not limited to the embodiment and includes various modifications and equivalent modifications. In addition, various combinations and configurations, as well as other combinations and configurations that include only one element, more, or less, fall within the scope and spirit of the present disclosure.

For example, in the above-described embodiment, the case where V is used as an element that substitutes for Si sites and N is used as an element that substitutes for C sites has been described as an example, but other elements can also be used. For example, elements that can substitute for Si sites include Al and P, in addition to V, while elements that can substitute for C sites include B, in addition to N.

In the above-described embodiment, V is used as the element that substitutes for Si site, and N is used as the element that substitutes for C sites. Therefore, when the V concentration in the first layer 21 is made uniform at the center portion Ra and the outer edge portion Rb, the N concentration at the center portion Ra is lower than that at the outer edge portion Rb. This is also just an example, and the conditions for the C/Si ratio should be set according to the elements used.

That is, in the first layer 21, when the concentration of the element that does not control the conductivity type is made the same at the center portion Ra and the outer edge portion Rb, the concentration of the element that controls the conductivity type may be higher at the center portion Ra than at the outer edge portion Rb. In this case, during the growth of the second layer 22, the concentration of the element that does not control the conductivity type is set to almost zero, and for the element that controls the conductivity type, the C/Si ratio conditions are set so that the concentration relationship between the center portion Ra and the outer edge portion Rb is reversed from that in the first layer 21. It should be noted that the element that controls the conductivity type means an n-type impurity element when making the SiC semiconductor layer 20 n-type, and a p-type impurity element when making the SiC semiconductor layer 20 p-type. The element that does not control the conductivity type includes, in addition to an element such as V that is not an n-type or p-type impurity element, a p-type impurity element that has the opposite conductivity type when making the SiC semiconductor layer 20 n-type.

In the above-described embodiment, the relationship in concentration of the doping elements may be reversed for each set of the first layer 21 and the second layer 22 formed in the order of forming the first layer 21 on the SiC semiconductor substrate 10 and then forming the second layer 22 on the first layer 21. That is, the second layer 22 is doped with N so that the conductivity type becomes n-type, and is also doped with V to restrict current-introduced degradation of the diode. The first layer 21 is doped with N as an element, or is doped with N and V as elements while the doping amount of V is made sufficiently smaller than that of the second layer 22. In this way, in the first layer 21, the center portion Ra has a higher N concentration than the outer edge portion Rb, and in the second layer 22, the center portion Ra has a lower N concentration than the outer edge portion Rb, thereby obtaining the same effect as in the above-described embodiment. Furthermore, in the above-described embodiment, the SiC semiconductor wafer is described as being disk-shaped, but this does not mean that the outer shape is a perfect circle. The wafer may have a partially linear orientation flat formed thereon, or may have a notch cut out of a portion of an outer periphery.

In the case of indicating the crystal orientation, a bar (-) should be added over a desired number properly. Since there is restriction on expression based on electronic filing, in the present specification, a bar is attached before a desired number.

What is claimed is:

1. A silicon carbide semiconductor wafer having a disk shape and having a center portion and an outer edge portion, the silicon carbide semiconductor wafer comprising:
a silicon carbide semiconductor substrate; and
a silicon carbide semiconductor layer formed of an epitaxially grown layer on the silicon carbide semiconductor substrate, wherein
the silicon carbide semiconductor layer includes a first layer and a second layer,
the first layer is doped with an element that controls a conductivity type of the silicon carbide semiconductor layer and an element that does not control the conductivity type of the silicon carbide semiconductor layer, one of the elements substitutes for Si sites and another of the elements substitutes for C sites, and within a plane of the first layer, a concentration of the element that controls the conductivity type is different at the center portion and the outer edge portion, and a concentration of the element that does not control the conductivity type is uniform at the center portion and the outer edge portion, and
the second layer is doped with the element that controls the conductivity type, and is not doped with the element that does not control the conductivity type or is doped with the element that does not control the conductivity type at a lower concentration than the first layer, and within a plane of the second layer, a high and low concentration relationship of the element that controls the conductivity type at the center portion and the outer edge portion is reversed from that in the first layer.

2. The silicon carbide semiconductor wafer according to claim 1, wherein
the first layer and the second layer are continuously laminated to form a set, and
the silicon carbide semiconductor layer includes a plurality of sets of the first layer and the second layer that are repeatedly laminated.

3. The silicon carbide semiconductor wafer according to claim 1, wherein
the second layer is laminated on the first layer,
the first layer and the second layer are doped with N as the element that controls the conductivity type and that substitutes for the C sites,
the first layer is doped with V as the element that does not control the conductivity type and that substitutes for the Si sites,
in the first layer, the center portion has a lower N concentration than the outer edge portion, and
in the second layer, the center portion has a higher N concentration than the outer edge portion.

4. The silicon carbide semiconductor wafer according to claim 1, wherein
the second layer is laminated on the first layer,
the first layer and the second layer are doped with N as the element that controls the conductivity type and that substitutes for the C sites,
the first layer is doped with V as the element that does not control the conductivity type and that substitutes for the Si sites,
in the first layer, the center portion has a higher N concentration than the outer edge portion, and
in the second layer, the center portion has a lower N concentration than the outer edge portion.

5. A manufacturing method of a silicon carbide semiconductor wafer having a disk shape and having a center portion and an outer edge portion, the manufacturing method comprising:
preparing a silicon carbide semiconductor substrate; and
epitaxially growing a silicon carbide semiconductor layer on the silicon carbide semiconductor substrate, wherein
the epitaxially growing of the silicon carbide semiconductor layer includes forming a first layer and forming a second layer,
the forming of the first layer includes doping with an element that controls a conductivity type of the silicon carbide semiconductor layer and an element that does not control the conductivity type of the silicon carbide semiconductor layer such that, within a plane of the first layer, a concentration of the element that controls the conductivity type is different at the center portion and the outer edge portion, and a concentration of the element that does not control the conductivity type is uniform at the center portion and the outer edge portion, one of the elements substitutes for Si sites and another of the elements substitutes for C sites, and
the forming of the second layer includes doping with the element that controls the conductivity type, and not doping with the element that does not control the conductivity type or doping with the element that does not control the conductivity type at a lower concentration than the first layer such that, within a plane of the second layer, a high and low concentration relationship of the element that controls the conductivity type at the center portion and the outer edge portion is reversed from that in the first layer.

6. A silicon carbide semiconductor device comprising:
a silicon carbide semiconductor substrate; and
a silicon carbide semiconductor layer formed of an epitaxially grown layer on the silicon carbide semiconductor substrate, and forming a buffer layer, wherein
the silicon carbide semiconductor layer includes a first layer and a second layer,
the first layer is doped with an element that controls a conductivity type of the silicon carbide semiconductor layer and an element that does not control the conductivity type of the silicon carbide semiconductor layer, one of the elements substitutes for Si sites and another of the elements substitutes for C sites, and
the second layer is doped with the element that controls the conductivity type, and is not doped with the element that does not control the conductivity type or is doped with the element that does not control the conductivity type at a lower concentration than the first layer.
